(19) United States
(12) Patent Application Publication
(10) Pub. No.: US 2010/0133532 A1
(43) Pub. Date: Jun. 3, 2010

(54) COMPOUND SEMICONDUCTOR LIGHT EMITTING DEVICE

(75) Inventor: Do Yeol Ahn, Seoul (KR)

Correspondence Address: HUSCH BLACKWELL SANDERS LLP, 190 Carondelet Plaza, Suite 600, ST. LOUIS, MO, 63105, US

(73) Assignee: WOOREE LST CO., LTD., Ansan-si, Gyeonggi-do (KR)

(21) Appl. No.: 12/666,542

(22) PCT Filed: Jun. 25, 2008
(86) PCT No.: PCT/KR2008/003637

§ 371 Date: Dec. 23, 2009

(30) Foreign Application Priority Data
Jul. 4, 2007 (KR) 10-2007-0066974

(51) Int. Cl. H01L 33/00

(52) U.S. Cl. 257/43; 257/97; 257/E33.005; 257/E33.013

(57) ABSTRACT

There is provided a compound semiconductor light emitting device capable of optimizing strain applied to an active layer and a clad layer to minimize a piezoelectric field and spontaneous polarization in an active layer and to maximize light emission efficiency. In a compound semiconductor light emitting device having a structure in which a buffer layer, a first clad layer, an active layer, and a second clad layer arc sequentially deposited, a strain induction layer and a strain control layer intersect at least once and are deposited between the buffer layer and the first clad layer, the strain induction layer performs induction so that compressive strain to be applied to the active layer is dispersed to the strain control layer, and the compressive strain applied to the active layer is reduced as the compressive strain is applied to the strain control layer.

### TECHNICAL FIELD

The present invention relates to a compound semiconductor light emitting device and, more particularly, to a compound semiconductor light emitting device capable of optimizing strain applied to an active layer and a clad layer to minimize a piezoelectric field and spontaneous polarization in an active layer and to maximize light emission efficiency.

### BACKGROUND ART

A group III-V nitride semiconductor light emitting device or group II-VI oxide semiconductor can realize a blue-purple color and a blue-green color and are applied to various fields such as a flat panel display, optical communication, and the like.

The light emitting device using the group III-V nitride semiconductor or the group II-VI oxide semiconductor is formed of a multilayer thin film including an active layer and a clad layer. In the case of the light emitting device using the group III-V nitride semiconductor, since the lattice parameter of the active layer is different from that of the clad layer, stress is applied to the active layer. Therefore, a piezoelectric field and spontaneous polarization are caused so that a light emission characteristic deteriorates.

In order to minimize the piezoelectric field and the spontaneous polarization, a method of using a non-polar substrate or a semi-polar substrate and a method of forming the clad layer of four original layers and of increasing the composition ratio of aluminum (Al) to improve the restraint effect of a transporter and to improve light emission efficiency are provided. In the former method, since a growth technology of the growth directions of different kinds of crystals has not been fully developed, a large number of defects are generated when the light emitting device is manufactured. Therefore, the characteristics of the light emitting device are not as excellent as theoretically expected. The former method is described in Park et al., Phys Rev B 59, 4725 (1999), Waltereit et al., Nature 406, 865 (2000), and Park & Ahn, Appl. Phys. Lett. 90, 013505 (2007).

On the other hand, in the latter method, the piezoelectric field and the spontaneous polarization cannot be removed and it is difficult to increase the Al composition ratio of the clad layer. The latter method is described in Zhang et al., Appl. Phys. Lett. 77, 2668 (2000) and Lai et al., IEEE Photonics Technol Lett. 13, 559 (2001).

In the light emitting device using the group II-VI oxide semiconductor, it is necessary to reduce the piezoelectric field and the spontaneous polarization although the piezoelectric field and the spontaneous polarization in the light emitting device using the group II-VI oxide semiconductor are smaller than the piezoelectric field and the spontaneous polarization in the light emitting device using the group III-V nitride semiconductor.

### DISCLOSURE OF INVENTION

### Technical Problem

Therefore, the present invention has been made in view of the above problems, and it is an object of the present invention to provide a compound semiconductor light emitting device capable of optimizing strain applied to an active layer and a clad layer to minimize a piezoelectric field and spontaneous polarization in an active layer and to maximize light emission efficiency.

### Technical Solution

In accordance with an aspect of the present invention, the above and other objects may be accomplished by the provision of a compound semiconductor light emitting device having a structure in which a buffer layer, a first clad layer, an active layer, and a second clad layer are sequentially deposited and in which a strain induction layer and a strain control layer are provided between the buffer layer and the first clad layer.

The strain induction layer disperses and applies compressive strain to be applied to the active layer to the strain control layer. As uniform compressive strain is applied to the strain control layer, the compressive strain applied to the active layer is reduced and tensile strain applied to the first and second clad layers is increased by the amount of reduction in the compressive strain.

Therefore, a piezoelectric field and spontaneous polarization on a boundary between the first clad layer and the active layer and a piezoelectric field and spontaneous polarization on a boundary between the second clad layer and the active layer have opposite signs, so that the piezoelectric field and the spontaneous polarization applied to the active layer are minimized.

The strain induction layer and the strain control layer are deposited while intersecting with each other at least once. When the plurality of strain control layers are provided, the strain induction layer may be interposed between the strain control layers.

In addition, group III-V nitride semiconductor or group II-VI oxide semiconductor is used for the compound semiconductor light emitting device. When the group III-V nitride semiconductor is used, as illustrated in FIG. 1, the buffer layer, the first clad layer, the active layer, and the second clad layer are formed of a material of the general formula of InₓAl_{y}Ga_{1-y}N (0≦x≦1, 0<y<1), the strain induction layer is formed of a material of the general formula of AlₓGa₁₋ₓN (0≦x<1), and the strain control layer is formed of a material of the general formula of InₓGa₁₋ₓN (0<x<0.33) (that is, a homogeneous layer) or has a structure in which a plurality of super lattice layers of In_{y}Ga_{1-y}N/GaN (0<y<0.33) are deposited. In addition, when the group II-VI oxide semiconductor is used, as illustrated in FIG. 2, the active layer is formed of ZnO, the buffer layer and the first and second clad layers are formed of a material of the general formula of MgₓZn₁₋ₓO (0<x<0.33), the strain induction layer is formed of a material of the general formula of MgₓZn₁₋ₓO (0<x<1), and the strain control layer has a structure in which a plurality of super lattice layers of Mg_{y}Zn_{1-y}O/Mg_{z}Zn_{1-z}O (0<y<0.33, 0<z<0.33, z<x, y) are deposited.

The strain control layer may be formed of a single layer or a plurality of layers. The thickness of a unit strain control layer that constitutes a single layer or a plurality of layers may be 10 nm to 30 nm. The thickness of the entire strain control layer may be 10 nm to 100 nm. Here, when the strain control layer is formed of the plurality of layers, the strain control layer may be formed of two to ten unit strain control layers. In addition, when the strain control layer has the structure in which the plurality of super lattice layers are deposited, the thickness of each super lattice layer may be 1 nm to 2 nm.

As described above, the strain induction layer intersects the strain control layer and is deposited on the strain control layer. When the strain control layer is formed of the plurality of layers, the strain induction layer may be formed of a plurality of layers. When the strain control layer is formed of the plurality of layers, the strain control layers may contact the buffer layer and the first clad layer and the strain induction layer may be provided between the strain control layers. The thickness of the unit strain induction layer that constitutes the single layer or the plurality of layers may be 10 nm to 30 nm.

### Advantageous Effects

The compound semiconductor light emitting device according to the present invention may provide the following advantageous effects.

Since the strain control layer is provided between the buffer layer and the first clad layer, the compressive strain applied to the active layer is reduced and the tensile strain applied to the first and second clad layers is increased, so that the piezoelectric field and the spontaneous polarization in the active layer may be minimized. Therefore, the spontaneous emission characteristic of the light emitting device may be improved.

In addition, the strain control layer may perform the function of a distributed Bragg reflector (DBR) due to a difference in the dielectric constants of the thin layers that constitute the light emitting device to totally reflect the light generated by the active layer and to improve the optical efficiency of the light emitting device.

### BRIEF DESCRIPTION OF THE DRAWINGS

The above and other objects, features and other advantages of the present invention will be more clearly understood from the following detailed description taken in conjunction with the accompanying drawings, in which:

FIG. 1 illustrates the structure of a group III-V nitride semiconductor light emitting device according to the present invention;

FIG. 2 illustrates the structure of a group II-VI oxide semiconductor light emitting device according to the present invention;

FIGS. 3 to 5 illustrate a light emitting device without a strain control layer, a light emitting device with one strain control layer, and a light emitting device with two strain control layers;

FIG. 6 illustrates spontaneous emission characteristics depending on the number of strain control layers of the light emitting devices illustrated in FIGS. 3 to 5;

FIGS. 7 to 10 illustrate a light emitting device without a strain control layer, a light emitting device in which the thickness of a unit strain control layer is 12.5 nm, a light emitting device in which the thickness of the unit strain control layer is 20 nm, and a light emitting device in which the thickness of the unit strain control layer is 25 nm;

FIG. 11 illustrates spontaneous emission characteristics depending on the amounts of indium (In) in the strain control layers; and

FIGS. 12 to 14 illustrate a light emitting device without a strain control layer, a light emitting device in which a strain control layer is formed of a super lattice layer, and a light emitting device in which a strain control layer is formed of a homogeneous layer.

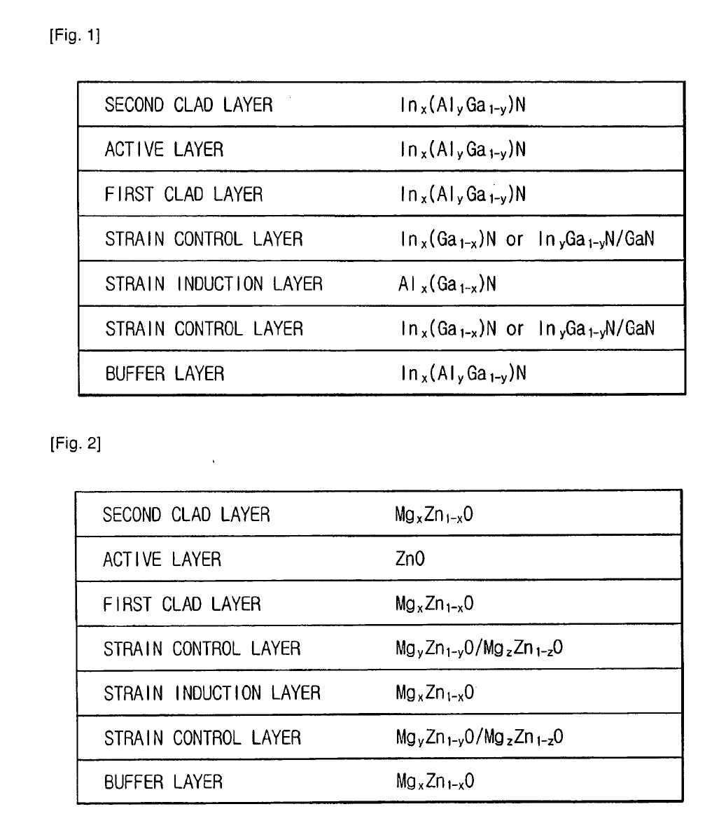

### MODE FOR THE INVENTION

According to the present invention, a strain induction layer and a strain control layer may be provided in a light emitting device so that strain applied to the first and second clad layers and the active layer of the light emitting device is optimized and that a piezoelectric field and spontaneous polarization in the active layer are minimized. In a structure where a plurality of layers are deposited, strain applied to each layer and a piezoelectric field and spontaneous polarization generated by a corresponding layer due to corresponding strain are analyzed by the following mathematical method.

First, in a structure formed of i thin layers, strain and stress applied to each layer will be mathematically described as follows. For reference, the strain and the stress applied to each layer are mathematically analyzed by a method suggested by Nakajima [Nakajima, J. Appl. Phys. 72, 5213 (1992)].

When it is defined that stress applied to an ith layer is Fᵢ, that the moment of the ith layer is Mᵢ, that the thickness of the ith layer is dᵢ, that the lattice parameter of the ith layer is aᵢ, that the Young's modulus of the ith layer is Eᵢ, and that the curvature of the structure formed of the i thin layers is R, the stress applied to the ith layer is represented by the following Equation 1.

$${F}_{i} \text{:} force per unit length \\ {M}_{i} \text{:} moment {M}^{} = {F}^{} \times {r}^{} \\ {\sum }_{i} {F}_{i} = 0 \\ {\sum }_{i} {M}_{i} + {\sum }_{i} {F}_{i} ( {\sum }_{j < i} {d}_{j} ) = 0 , {M}_{i} = \frac{{E}_{i} {d}_{i}^{2}}{12 R} \qquad [ Equation 1 ]$$

The condition under which the ith layer and an (i+1)th layer are in equilibrium with each other is represented in the following Equation 2.

$${l}_{i} = {a}_{i} ( 1 + {α}_{i} T ) \\ {l}_{i + 1} [ 1 + {e}_{i + 1} ( {F}_{i + 1} ) - {e}_{i + 1} ( {M}_{i + 1} ) ] = {l}_{i} [ 1 + {e}_{i} ( {F}_{i} ) + {e}_{i} ( {M}_{i} ) ] \\ {e}_{i} ( {F}_{i} ) = \frac{{F}_{i}}{{E}_{i} {d}_{i}} , {E}_{i} \text{:} Young ' s modulus \\ {e}_{i} ( {M}_{i} ) = \frac{{d}_{i}}{2 R} \qquad [ Equation 2 ]$$

(wherein, lᵢ represents the effective lattice parameter of the ith layer in consideration of thermal expansion, T represents the temperature of a lattice, and eᵢ represents strain applied to the ith layer)

The stress and the strain applied to the ith layer are obtained by combining the Equation 1 and the Equation 2 as represented by Equation 3.

$${F}_{i} = \frac{{E}_{i} {d}_{i}}{{a}_{i} {\sum }_{j} ( {E}_{j} {d}_{j} / {a}_{j} )} \times [ \begin{matrix}\frac{1}{R} {\sum }_{j} ( \frac{{E}_{j} {d}_{j}}{{a}_{j}} ) \{ \begin{matrix}{\sum }_{k < i} {a}_{k} {d}_{k} - \\ \begin{matrix}{\sum }_{k < j} {a}_{k} {d}_{k} + \\ \frac{{a}_{i} {d}_{i} - {a}_{j} {d}_{j}}{2}\end{matrix}\end{matrix} \} + \\ {\sum }_{j} ( \frac{{E}_{j} {d}_{j}}{{a}_{j}} ) ( {l}_{j} - {l}_{i} )\end{matrix} ] \\ {ɛ}_{xxi} = \frac{{F}_{i}}{{E}_{i} {d}_{i}} + \frac{{d}_{i}}{2 R} \qquad [ Equation 3 ]$$

(wherein, eₓₓᵢ represents effective strain applied to the ith layer)

The curvature R of the structure formed of the thin layers is represented by Equation 4.

$$\frac{1}{R} = \frac{{R}_{3}}{{R}_{1} + {R}_{2}} \\ {R}_{1} = ( {\sum }_{i} {E}_{i} {d}_{i}^{3} ) ( {\sum }_{l} \frac{{E}_{l} {d}_{l}}{{a}_{t}} ) \\ {R}_{2} = 3 {\sum }_{i} \frac{{E}_{i} {d}_{i}}{{a}_{i}} ( {d}_{i} + 2 {\sum }_{j < i} {d}_{j} ) \times [ {\sum }_{j} ( \frac{{E}_{j} {d}_{j}}{{a}_{j}} ) \{ \begin{matrix}\begin{matrix}2 {\sum }_{k < i} {a}_{k} {d}_{k} - \\ 2 {\sum }_{k < j} {a}_{k} {d}_{k} +\end{matrix} \\ {a}_{i} {d}_{i} - {a}_{j} {d}_{j}\end{matrix} \} ] \\ {R}_{3} = 6 {\sum }_{i} \frac{{E}_{i} {d}_{i}}{{a}_{i}} ( {d}_{i} + 2 {\sum }_{j < i} {d}_{j} ) ( {\sum }_{j} \frac{{E}_{j} {d}_{j}}{{a}_{j}} ( {l}_{i} - {l}_{j} ) ) \qquad [ Equation 4 ]$$

As seen in the Equation 1, the sum of the stresses applied to the structure formed of the plurality of thin layers is 0, and, from the Equations 2 to 4, it may be seen that the strain is properly distributed to each thin layer. When the above principle is applied to the present invention, in the case where induction is made so that the compressive strain is applied to a specific thin layer (the strain control layer), the compressive strain applied to another thin layer (the active layer) may be reduced.

The piezoelectric field and the spontaneous polarization applied to each layer may be calculated using the strain calculated by the Equations 1 to 4. The piezoelectric field and the spontaneous polarization using the strain are analyzed by a method provided by Bernardini [Phys. Stat. Sol. (b) 216,392 (1999)] using the following Equation 5.

$${P}_{zi} = 2 {d}_{31} ( {c}_{11} + {c}_{12} - \frac{2 {c}_{13}^{2}}{{c}_{33}} ) {ɛ}_{xxi} \\ {P}_{t} = {P}_{z} + {P}_{sp} \\ {D}_{j} = {ɛ}_{j} {E}_{j} + {P}_{ij} \\ {\sum }_{k} {d}_{k} {E}_{k} = 0 ; periodic boundary condition \\ {E}_{i} = \frac{{\sum }_{k} {d}_{k} {P}_{tk} / {ɛ}_{k} - {P}_{ti} {\sum }_{k} {d}_{k} / {ɛ}_{k}}{{ɛ}_{i} {\sum }_{k} {d}_{k} / {ɛ}_{k}} \qquad [ Equation 5 ]$$

(wherein, Eᵢ represents an effective electric field caused by the piezoelectric field and the spontaneous polarization applied to the ith layer)

Hereinafter, an example embodiment of a compound semiconductor light emitting device according to the present invention will be described with reference to the drawings.

Strain and Spontaneous Polarization Characteristics Depending on the Number of Strain Control Layers

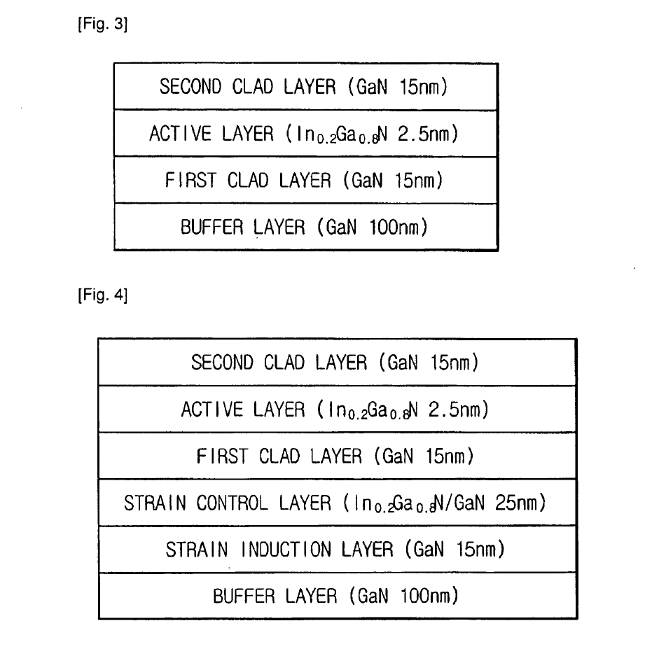

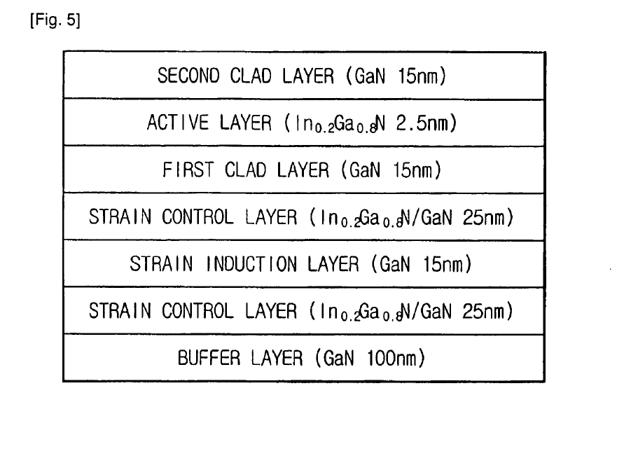

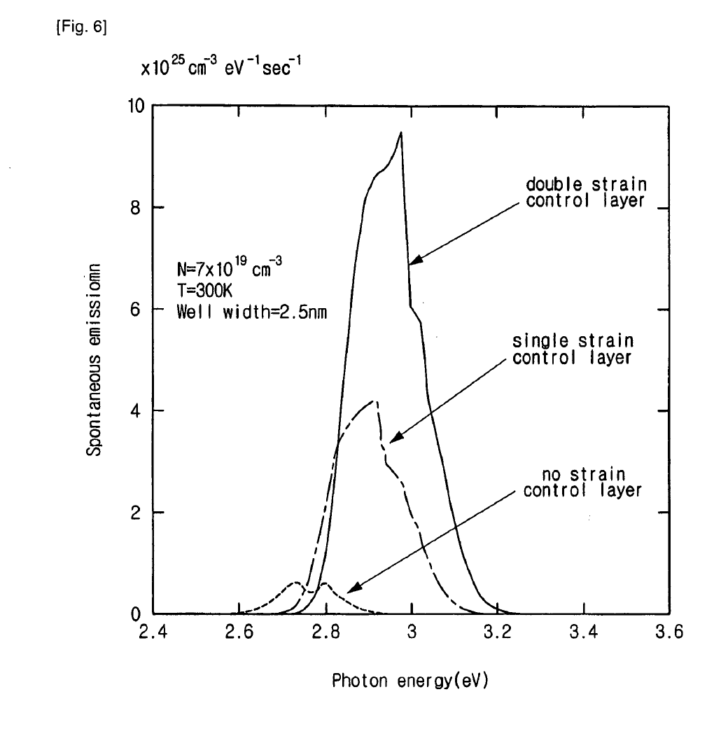

FIGS. 3 to 5 illustrate a light emitting device without a strain control layer SCL, a light emitting device with one strain control layer, and a light emitting device with two strain control layers. Table 1 shows strain and spontaneous polarization characteristics depending on the number of strain control layers of the light emitting devices illustrated in FIGS. 3 to 5. FIG. 6 illustrates spontaneous emission characteristics depending on the number of strain control layers of the light emitting devices illustrated in FIGS. 3 to 5.

TABLE 1
Strain and spontaneous polarization characteristics depending
on the number of strain control layers

| | No SCL | One SCL | Two SCLs |
|---|---|---|---|
| Active layer strain (%) | −2.19 | −2.02 | −1.924 |
| Clad layer strain (%) | 0.035 | 0.207 | 0.308 |
| Active layer spontaneous polarization | 3.11 | 2.89 | 2.76 |
| (MV/cm) | | | |
| Clad layer spontaneous polarization | −0.05 | −0.34 | −0.52 |
| (MV/cm) | | | |
| Light emission peak (A.U.) | 1.093 | 4.321 | 9.503 |

The light emitting devices illustrated in FIGS. 3 to 5 are light emitting devices using group III-V nitride semiconductor. To be specific, the first and second clad layers and the buffer layer are formed of GaN, the active layer is formed of InₓGa₁₋ₓN (x=2), the strain induction layer is formed of GaN, and the strain control layer has a structure in which a plurality of super lattice layers formed of In_{y}Ga_{1-y}N/GaN (y=0.2) are deposited. The thickness of each of the first and second clad layers is 15 nm, the thickness of the active layer is 2.5 nm, the thickness of the buffer layer is 100 nm, the thickness of the unit strain control layer is 25 nm, and the thickness of the strain induction layer is 15 nm.

The strain and spontaneous polarization characteristics of the light emitting devices having the above structures will be described. As illustrated in Table 1, as the number of strain control layers is increased, the strain applied to the active layer, that is, the compressive strain is reduced and the strain applied to the first and second clad layers, that is, tensile strain is increased. In addition, as the number of strain control layers is increased, the spontaneous polarization in the active layer is reduced and the spontaneous polarization of the first and second clad layers is increased, so that spontaneous polarizations on a boundary between the first clad layer and the active layer and on a boundary between the second clad layer and the active layer are reduced. On the other hand, when the number of strain control layers is increased, an operating voltage is increased and the diffusion length of electrons is increased. As a result, the number of strain control layers needs to be limited.

On the other hand, as illustrated in FIG. 6, as the number of strain control layers is increased, the spontaneous emission characteristic is improved. As a result, the strain applied to the active layer and the first and second clad layers changes due to the strain control layer, and the effective electric field of the piezoelectric field and the spontaneous polarization is offset and the degree to which an optical characteristic is improved is increased.

Strain and Spontaneous Polarization Characteristics Depending on the Thickness of the Strain Control Layer

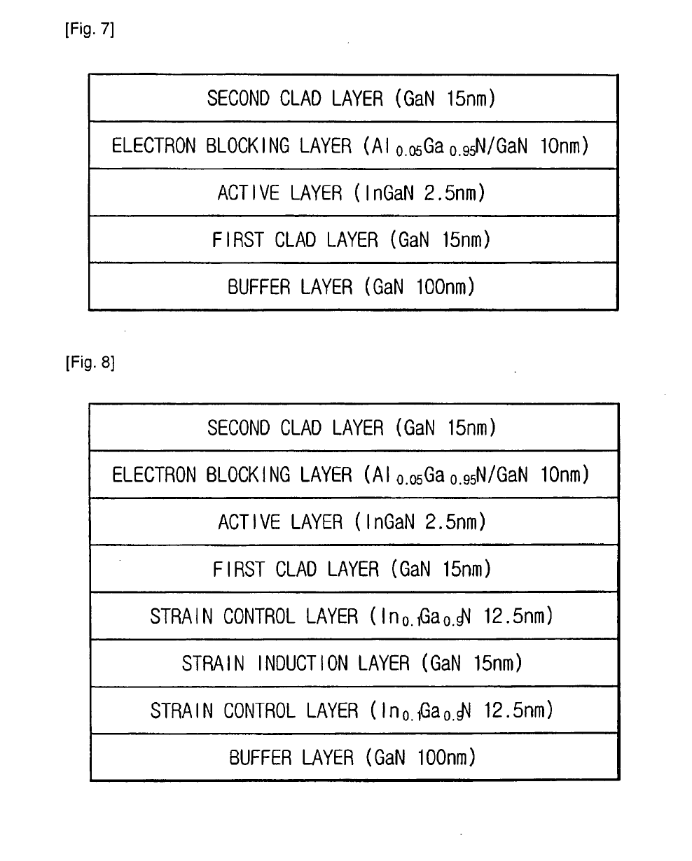

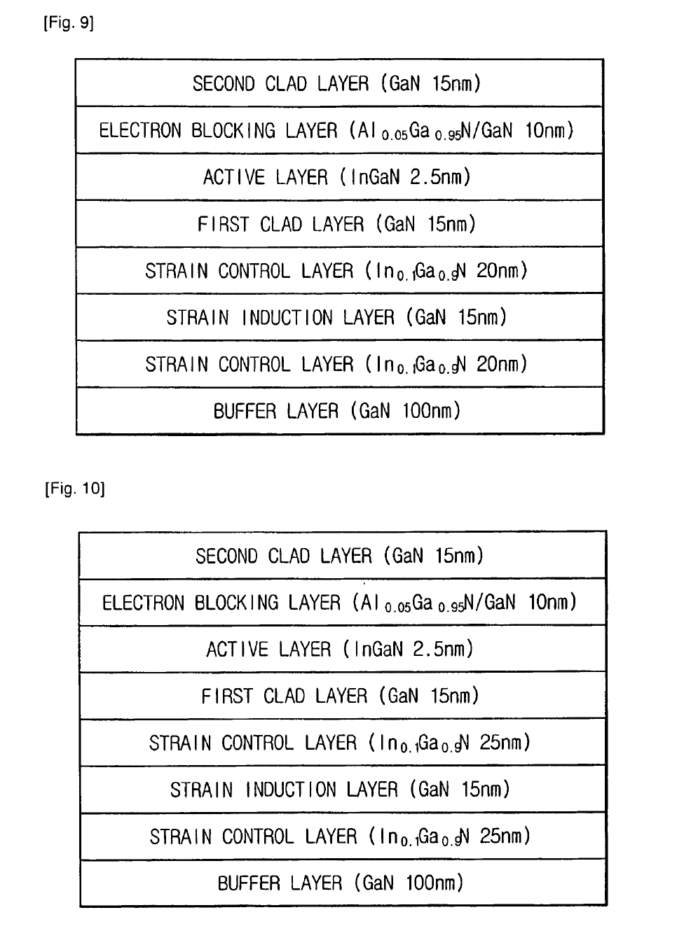

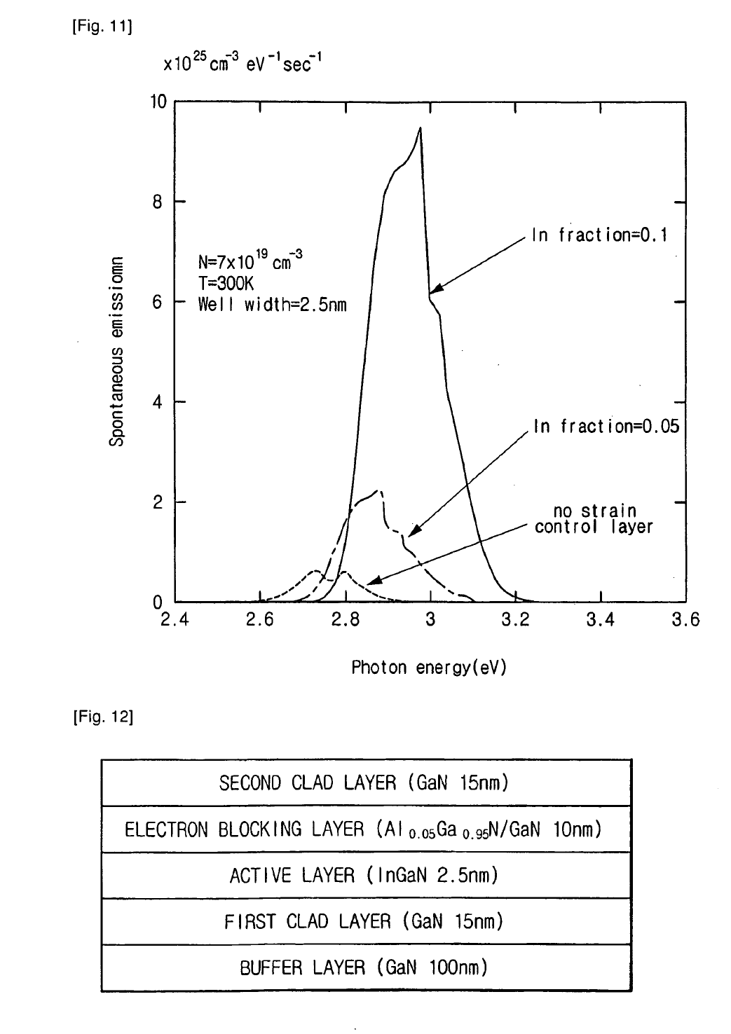

FIGS. 7 to 10 illustrate a light emitting device without a strain control layer, a light emitting device in which the thickness of a unit strain control layer is 12.5 nm, a light emitting device in which the thickness of the unit strain control layer is 20 nm, and a light emitting device in which the thickness of the unit strain control layer is 25 nm. Table 2 illustrates the strain and spontaneous polarization characteristics depending on the thicknesses of the strain control layers of the light emitting devices illustrated in FIGS. 7 to 10. FIG. 11 illustrates spontaneous emission characteristics depending on the amounts of indium (In) in the strain control layers. In FIGS. 7 to 10, the number of unit strain control layers is two.

TABLE 2
Strain and spontaneous polarization characteristics depending
on the thicknesses of the strain control layers

| | | | SCL = | SCL = |
|---|---|---|---|---|
| | No SCL | SCL = 12.5 nm | 20 nm | 25 nm |
| Active layer strain (%) | −2.19 | −2.038 | −1.96 | −1.924 |
| Clad layer strain (%) | 0.035 | 0.192 | 0.265 | 0.308 |
| Active layer spontaneous | 3.11 | 2.91 | 2.82 | 2.76 |
| polarization (MV/cm) | | | | |
| Clad layer spontaneous | −0.05 | −0.315 | −0.44 | −0.52 |
| polarization (MV/cm) | | | | |
| Light emission peak (A.U.) | 1.093 | 3.299 | 6.969 | 9.503 |

The light emitting devices illustrated in FIGS. 7 to 10 are light emitting devices using group III-V nitride semiconductor. To be specific, the first and second clad layers and the buffer layer are formed of GaN, the active layer is formed of InGaN, the strain induction layer is formed of GaN, and the strain control layer is formed of In_{y}Ga_{1-y}N (y=0.1). An electron blocking layer having a thickness of 10 nm, that is, AlₓGa₁₋ₓN/GaN (x=0.05) is provided between the second clad layer and the active layer. The thickness of each of the first and second clad layers is 15 nm, the thickness of the active layer is 2.5 nm, the thickness of the buffer layer is 100 nm, and the thickness of the strain induction layer is 15 nm. Here, the electron blocking layer prevents surplus electrons from flowing into the second clad layer, thereby improving efficiency of a p-type transporter being injected into the active layer.

The strain and spontaneous polarization characteristics of the light emitting devices having the above structures will be described. As seen in Table 2, as the thickness of the strain control layer is increased, the compressive strain applied to the active layer is reduced and the tensile strain applied to the first and second clad layers is increased. In addition, as the thickness of the strain control layer is increased, the spontaneous polarization in the active layer is reduced and the spontaneous polarization of the first and second clad layers is increased, so that the spontaneous polarizations on the boundary between the first clad layer and the active layer and on the boundary between the second clad layer and the active layer are reduced.

On the other hand, as illustrated in FIG. 11, when the number of unit strain control layers having a thickness of 25 nm is two, as the amount of the Indium of the corresponding strain control layer is increased, the spontaneous emission characteristic is improved. That is, the amount of the Indium in the strain control layer is increased, so that the effective electric field of the piezoelectric field and the spontaneous polarization applied to the active layer is offset and that the optical characteristic may be improved. For reference, the optical characteristic analyses of the Tables 1 to 3 and FIGS. 6 and 11 are performed using a model suggested by Ahn [Ahn, IEEE J. Quantum Electron. 34, 344 (1998) & Ahn et al., IEEE J. Quantum Electron. 41, 1253 (2005)].

Piezoelectric Field and Spontaneous Polarization Characteristics Depending on the Structures of the Thin Layers of the Strain Control Layers

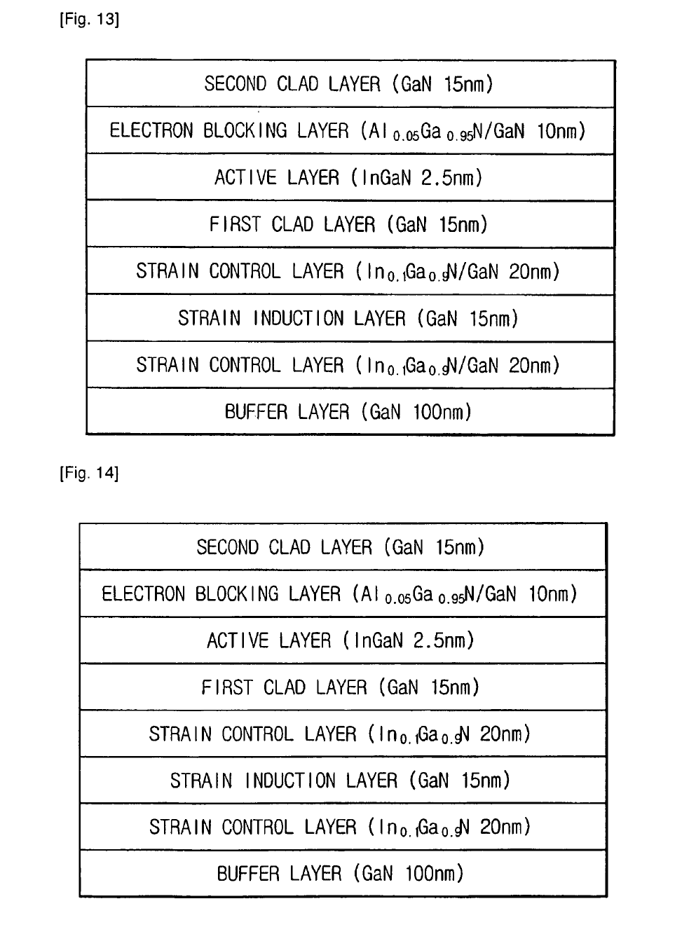

FIGS. 12 to 14 illustrate a light emitting device without a strain control layer, a light emitting device in which a strain control layer is formed of a super lattice layer, and a light emitting device in which a strain control layer is formed of a homogeneous layer. Table 3 illustrates strain and spontaneous polarization characteristics depending on the structures of the strain control layers of the light emitting devices of FIGS. 12 to 14. In FIGS. 13 and 14, the number of unit strain control layers is two.

TABLE 3
Strain and spontaneous polarization characteristics depending
on the structures of the strain control layers

| | | Supper | |
|---|---|---|---|
| | | lattice layer | Homogeneous |
| | No SCL | structure | layer structure |
| Active layer strain (%) | −2.19 | −1.976 | −1.960 |
| Clad layer strain (%) | 0.035 | 0.255 | 0.265 |
| Active layer spontaneous | 3.11 | 2.85 | 2.82 |
| polarization (MV/cm) | | | |
| Clad layer spontaneous | −0.05 | −0.398 | −0.44 |
| polarization (MV/cm) | | | |
| Light emission peak (A.U.) | 1.093 | 6.362 | 6.969 |

The light emitting devices illustrated in FIGS. 12 to 14 are light emitting devices using group III-V nitride semiconductor. To be specific, the first and second clad layers and the buffer layer are formed of GaN, the active layer is formed of InGaN, the strain induction layer is formed of GaN, and the strain control layer is formed of In_{y}Ga_{1-y}N (y=0.1). An electron blocking layer having a thickness of 10 nm, that is, AlₓGa₁₋ₓ N/GaN (x=0.05) is provided between the second clad layer and the active layer. The thickness of each of the first and second clad layers is 15 nm, the thickness of the active layer is 2.5 nm, the thickness of the buffer layer is 100 nm, and the thickness of the strain induction layer is 15 nm.

The strain and spontaneous polarization characteristics of the light emitting devices having the above structures will be described. As seen in Table 3, similar characteristics are exhibited regardless of the structures of the strain control layers. That is, in the case where the strain control layer is formed of the super lattice layer and in the case where the strain control layer is formed of the homogeneous layer, the compressive strain applied to the active layer is reduced and the tensile strain applied to the first and second clad layers is increased. In addition, as the thickness of the strain control layer is increased, the spontaneous polarization in the active layer is reduced and the spontaneous polarization of the first and second clad layers is increased, so that the spontaneous polarizations on the boundary between the first clad layer and the active layer and on the boundary between the second clad layer and the active layer are reduced.

### INDUSTRIAL APPLICABILITY

The present invention relates to a compound semiconductor light emitting device and, more particularly, to a compound semiconductor light emitting device capable of optimizing strain applied to an active layer and a clad layer to minimize a piezoelectric field and spontaneous polarization in an active layer and to maximize light emission efficiency.

1. A compound semiconductor light emitting device having a structure in which a buffer layer, a first clad layer, an active layer, and a second clad layer are sequentially deposited,
wherein a strain induction layer and a strain control layer intersect at least once and are deposited between the buffer layer and the first clad layer,
wherein the strain induction layer performs induction so that compressive strain to be applied to the active layer is dispersed to the strain control layer, and
wherein the compressive strain is applied to the strain control layer so that the compressive strain applied to the active layer is reduced.

2. The compound semiconductor light emitting device as set forth in claim 1, wherein the compound semiconductor light emitting device is a light emitting device using group III-V nitride semiconductor.

3. The compound semiconductor light emitting device as set forth in claim 1, wherein the compound semiconductor light emitting device is a light emitting device using group III-VI oxide semiconductor.

4. The compound semiconductor light emitting device as set forth in claim 1, wherein the strain control layer is formed of a single unit strain control layer or a plurality of unit strain control layers.

5. The compound semiconductor light emitting device as set forth in claim 4, wherein the strain control layer is formed of one to ten unit strain control layers.

6. The compound semiconductor light emitting device as set forth in claim 4, wherein the thickness of the unit strain control layer is 10 nm to 30 nm.

7. The compound semiconductor light emitting device as set forth in claim 4, wherein the thickness of the strain control layer is 10 nm to 100 nm.

8. The compound semiconductor light emitting device as set forth in claim 4, wherein the unit strain control layer is formed of a homogeneous layer or has a structure in which a plurality of super lattice layers are deposited.

9. The compound semiconductor light emitting device as set forth in claim 8, wherein the thickness of the super lattice layer is 1 nm to 2 nm.

10. The compound semiconductor light emitting device as set forth in claim 2,
wherein the buffer layer, the first clad layer, the active layer, and the second clad layer are formed of a material of the general formula InₓAl_{y}Ga_{1-y}N (0≦x≦1, 0<y<1), and
wherein the strain control layer is formed of a material of the general formula Inₓ Ga₁₋ₓN (0<x<0.33) or has a structure in which a plurality of super lattice layers of In_{y}Ga_{1-y}N/GaN (0<y<0.33) are deposited.

11. The compound semiconductor light emitting device as set forth in claim 2, wherein the strain induction layer is formed of a material of the general formula AlₓGa₁₋ₓN (0≦x<1).

12. The compound semiconductor light emitting device as set forth in claim 3,
wherein the active layer is formed of ZnO,
wherein the buffer layer and the first and second clad layers are formed of a material of the general formula MgₓZn₁₋ₓO (0<x<0.33), and
wherein the strain control layer has a structure in which a plurality of super lattice layers of Mg_{y}Zn_{1-y}O/Mg_{z}Zn_{1-z}O (0<y<0.33, 0<z<0.33, z<x, y) are deposited.

13. The compound semiconductor light emitting device as set forth in claim 3, wherein the strain induction layer is formed of a material of the general formula MgₓZn₁₋ₓO (0<x<1).

14. The compound semiconductor light emitting device as set forth in claim 1, further comprising an electron blocking layer between the active layer and the second clad layer.

15. The compound semiconductor light emitting device as set forth in claim 1, wherein, when the strain control layer is formed of a plurality of layers, the strain control layer positioned in the uppermost end contacts the first clad layer and the strain control layer positioned in the lowermost end contacts the buffer layer.
